(19) United States
(12) Patent Application Publication
(10) Pub. No.: US 2026/0052783 A1
(43) Pub. Date: Feb. 19, 2026

(54) ELECTRONIC DEVICE

(71) Applicant: InnoLux Corporation, Miao-Li County (TW)

(72) Inventors: Bi-Ly LIN, Miao-Li County (TW); Yeong-E CHEN, Miao-Li County (TW)

(21) Appl. No.: 19/271,223

(22) Filed: Jul. 16, 2025

(30) Foreign Application Priority Data
Aug. 16, 2024 (CN) 202411126615.9

(51) Int. Cl. H10F 19/90

(52) U.S. Cl. CPC H10F 19/904

(57) ABSTRACT

An electronic device includes a first substrate, a second substrate, a light modulation layer, a first electrode layer, a second electrode layer, a photoelectric conversion component and a driving circuit. The second substrate is disposed opposite to the first substrate. The light modulation layer is disposed between the first substrate and the second substrate. The first electrode layer is disposed between the first substrate and the light modulation layer. The second electrode layer is disposed between the second substrate and the light modulation layer. The photoelectric conversion component is disposed between the first substrate and the second substrate. The driving circuit is disposed between the first substrate and the second substrate. The driving circuit is electrically connected to the photoelectric conversion component, and is electrically connected to the first electrode layer and the second electrode layer, respectively.

### CROSS-REFERENCE TO RELATED APPLICATIONS

This application claims the benefits of the Chinese Patent Application Serial Number 202411126615.9, filed on Aug. 16, 2024, the subject matter of which is incorporated herein by reference.

### BACKGROUND

### Field of the Disclosure

The present disclosure relates to an electronic device and, more particularly, to an electronic device including a photoelectric conversion component and a light modulation layer.

### Description of Related Art

In recent years, with the development of science and technology and the increasing attention paid to environmental protection awareness, various energy-saving and carbon-reducing products, such as smart windows, have emerged accordingly. The smart window is such a window that can be controlled by electric fields to present different optical states (such as light transmitting state, light shielding state or haze state) so as to change the light transmittance.

However, current smart windows have many disadvantages, such as the need for an external power source to control the smart window to switch between different optical modes.

Therefore, there is an urgent need to provide a novel electronic device to alleviate and/or obviate the aforementioned defects.

### SUMMARY

The present disclosure provides an electronic device, which comprises: a first substrate; a second substrate disposed opposite to the first substrate; a light modulation layer disposed between the first substrate and the second substrate; a first electrode layer disposed between the first substrate and the light modulation layer; a second electrode layer disposed between the second substrate and the light modulation layer; a photoelectric conversion component disposed between the first substrate and the second substrate; and a driving circuit disposed between the first substrate and the second substrate, wherein the driving circuit is electrically connected to the photoelectric conversion component, and the driving circuit is electrically connected to the first electrode layer and the second electrode layer, respectively.

The present disclosure further provides an electronic device, which comprises: a first substrate; a second substrate disposed opposite to the first substrate, wherein the first substrate has a first area overlapping with the second substrate, and a second area not overlapping with the second substrate; a light modulation layer disposed between the first substrate and the second substrate; a first electrode layer disposed between the first substrate and the light modulation layer; a second electrode layer disposed between the second substrate and the light modulation layer; a photoelectric conversion component disposed on the second area of the first substrate; and a driving circuit disposed between the first substrate and the second substrate, wherein the driving circuit is electrically connected to the photoelectric conversion component, and the driving circuit is electrically connected to the first electrode layer and the second electrode layer, respectively.

Other novel features of the disclosure will become more apparent from the following detailed description when taken in conjunction with the accompanying drawings.

### BRIEF DESCRIPTION OF DRAWINGS

FIG. 1 schematically illustrates a cross-sectional view of an electronic device according to an embodiment of the present disclosure;

FIG. 2 is a functional block diagram of an electronic device according to an embodiment of the present disclosure;

FIG. 3 schematically illustrates a cross-sectional view of an electronic device according to an embodiment of the present disclosure;

FIG. 4 schematically illustrates a cross-sectional view of an electronic device according to an embodiment of the present disclosure;

FIG. 5 is a voltage signal block diagram of an electronic device according to an embodiment of the present disclosure;

FIG. 6A and FIG. 6B schematically illustrate the top views of an electronic device according to an embodiment of the present disclosure;

FIG. 7 schematically illustrates a cross-sectional view of an electronic device according to an embodiment of the present disclosure;

FIG. 8 schematically illustrates a cross-sectional view of an electronic device according to an embodiment of the present disclosure;

FIG. 9 schematically illustrates the top view of an electronic device according to an embodiment of the present disclosure;

FIG. 10A schematically illustrates the top view of a photoelectric conversion component according to an embodiment of the present disclosure; and

FIG. 10B is a cross-sectional view of the photoelectric conversion component taken along line A-A′ of FIG. 10A.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided. Furthermore, in the specification and claims, unless otherwise specified, ordinal numbers, such as “first”, “second”, etc., used herein are intended to distinguish elements rather than disclose explicitly or implicitly that names of the elements bear the wording of the ordinal numbers. The ordinal numbers do not imply what order an element and another element are in terms of space, time or steps of a manufacturing method.

In the entire specification and the appended claims of the present disclosure, certain words are used to refer to specific components. Those skilled in the art should understand that electronic device manufacturers may refer to the same components by different names. The present disclosure does not intend to distinguish those components with the same function but different names. In the claims and the following description, the words “comprise”, “include” and “have” are open type language, and thus they should be interpreted as meaning “including but not limited to”. Therefore, when the terms “comprise”, “include” and/or “have” are used in the description of the present disclosure, they specify the existence of corresponding features, regions, steps, operations and/or components, but do not exclude the existence of one or more corresponding features, regions, steps, operations and/or components.

In the description, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values between the first and second values.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

It should be understood that, according to the embodiments of the present disclosure, an optical microscope (OM), a scanning electron microscope (SEM), a film thickness profiler (α-step), an ellipse thickness gauge or other suitable measurement means may be used to measure the depth, thickness, width or height of each component, or the spacing or distance between components. According to some embodiments, a scanning electron microscope may be used to obtain a cross-sectional structural image including the components to be measured, and measure the depth, thickness, width or height of each component, or the spacing or distance between components. In addition, there may be a certain error in any two values or directions used for comparison. If the first value is equal to the second value, it implies that there may be an error of about 10% between the first value and the second value. If the first direction is perpendicular to the second direction, the angle between the first direction and the second direction may be 80 to 100 degrees. If the first direction is parallel to the second direction, the angle between the first direction and the second direction may be 0 to 10 degrees.

In this disclosure, the electronic device may include a display device, a backlight device, an antenna device, a sensing device or a tiled device, but it is not limited thereto. The electronic device may be a bendable or flexible electronic device. The display device may be a non-self-luminous display device or a self-luminous display device. The antenna device may be a liquid crystal type antenna device or a non-liquid crystal type antenna device, and the sensing device may be a sensing device for sensing capacitance, light, thermal energy or ultrasonic waves, but it is not limited thereto. In the present disclosure, the electronic device may include electronic components, and the electronic components may include passive components and active components, such as capacitors, resistors, inductors, diodes, transistors, and the like. The diodes may include light emitting diodes or photodiodes. The light emitting diodes may, for example, include organic light emitting diodes (OLEDs), sub-millimeter light emitting diodes (mini LEDs), micro light emitting diodes (micro LEDs) or quantum dot light emitting diodes (quantum dot LEDs), but it is not limited to. The tiled device may be, for example, a tiled display device or a tiled antenna device, but it is not limited thereto. It is noted that the electronic device may be any permutation and combination of the aforementioned, but it is not limited thereto. In the following description, a display device is used as an electronic device to illustrate the content of the disclosure, but the present disclosure is not limited thereto.

In addition, the shape of the electronic device may be rectangular, circular, polygonal, shape with curved edges, or other suitable shapes. The electronic device may have peripheral systems such as a drive system, a control system, a light source system, a shelf system, etc. to support a display device, an antenna device or a tiled device.

It should be noted that the technical solutions provided by the different embodiments described hereinafter may be used interchangeably, combined or mixed to form another embodiment without violating the spirit of the present disclosure.

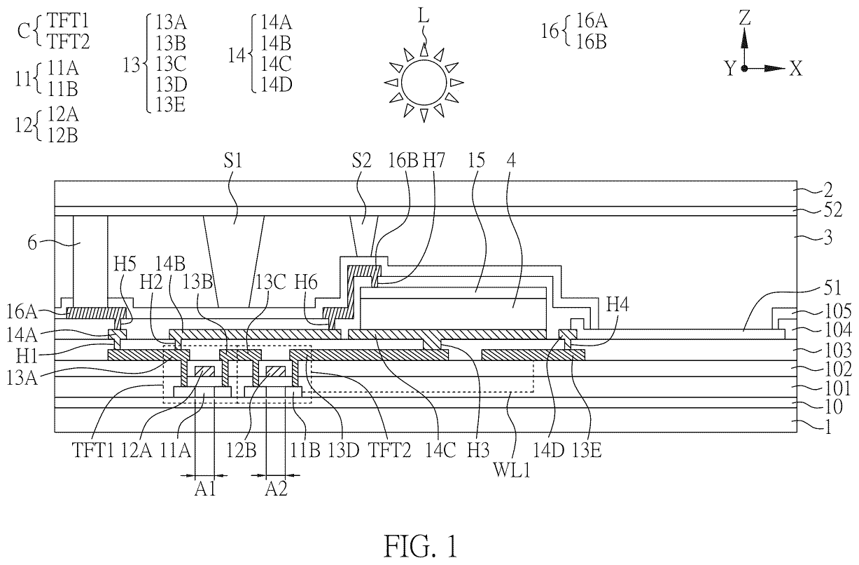

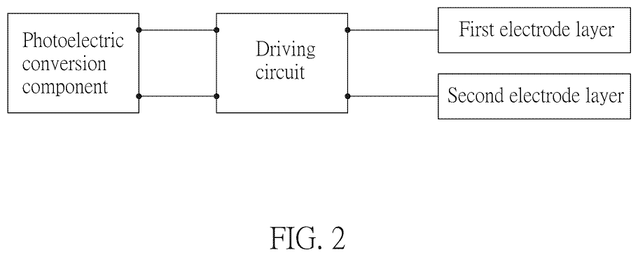

FIG. 1 schematically illustrates a cross-sectional view of an electronic device according to an embodiment of the present disclosure, and FIG. 2 is a functional block diagram of an electronic device according to an embodiment of the present disclosure.

In one embodiment of the present disclosure, as shown in FIG. 1, the electronic device may include: a first substrate 1; a second substrate 2 disposed opposite to the first substrate 1; a light modulation layer 3 disposed between the first substrate 1 and the second substrate 2; a photoelectric conversion component 4 disposed between the first substrate 1 and the second substrate 2; and a driving circuit C disposed between the first substrate 1 and the second substrate 2, wherein the driving circuit C is electrically connected to the photoelectric conversion component 4.

In one embodiment of the present disclosure, as shown in FIG. 1, the electronic device may also include: a first electrode layer 51 disposed between the first substrate 1 and the light modulation layer 3; and a second electrode layer 52 disposed between the second substrate 2 and the light modulation layer 3, wherein the driving circuit C is electrically connected to the first electrode layer 51 and the second electrode layer 52 respectively. In the present disclosure, by applying signals to the first electrode layer 51 and the second electrode layer 52 to control the light modulation layer 3, the light modulation layer 3 can be switched between the light shielding state and the light transmitting state, so that the electronic device may achieve the light shielding or light transmitting effect. In other embodiments, by applying signals to the first electrode layer 51 and the second electrode layer 52 to control the light modulation layer 3 so that the light modulation layer 3 can be switched between the haze state and the light transmitting state, the electronic device may achieve a haze or light transmitting effect. In one embodiment of the present disclosure, the electronic device may be applied to a smart window. The smart window may be selectively applied to architectural glass, car window glass or other applications. In addition to having light-adjustable functions according to the structural design, the smart window may also have heat insulation and/or sound insulation functions.

The present disclosure receives light through a photoelectric conversion component 4 (such as a solar cell) and converts light energy into electrical energy for being provided to the driving circuit C. The driving circuit C may provide signals to the first electrode layer 51 and the second electrode layer 52 respectively, and generate an electric field by applying signals (voltage) between the first electrode layer 51 and the second electrode layer 52 to drive the light modulation layer 3. By disposing the photoelectric conversion component 4, the electronic device may generate electric energy to control the light modulation layer 3 without disposing other external power sources, thereby achieving a power saving effect. In addition, when the photoelectric conversion component 4 is disposed between the first substrate 1 and the second substrate 2, the influence of other external environmental factors (such as moisture, air, etc.) on the photoelectric conversion component 4 may be reduced, thereby increasing the service life of the photoelectric conversion component 4.

In one embodiment of the present disclosure, as shown in FIG. 1, the electronic device may include: a semiconductor layer 11 including a first semiconductor 11A and a second semiconductor 11B; a gate insulation layer 101 disposed on the semiconductor layer 11; a first metal layer 12 disposed on the gate insulation layer 101 and including a first gate 12A and a second gate 12B, wherein the first gate 12A is disposed opposite to or overlaps the first semiconductor layer 11A, and the second gate 12B is disposed opposite to or overlaps the second semiconductor layer 11B; a first insulation layer 102 disposed on the first metal layer 12; a second metal layer 13 disposed on the first insulation layer 102 and provided with a first source 13A, a first drain 13B, a second source 13C and a second drain 13D, wherein the first source 13A and the first drain 13B are each electrically connected to the first semiconductor layer 11A, the second source 13C and the second drain 13D are each electrically connected to the second semiconductor, the first drain 13B and the second source 13C are electrically connected, and the second metal layer 13 may further include a metal portion 13E that may be electrically connected to the driving circuit C through the line WL1 (the dotted line in the figure indicates the electrical connection therebetween); and a second insulation layer 103 disposed on the second metal layer 13.

The first semiconductor 11A, the gate insulation layer 101, the first gate 12A, the first insulation layer 102, the first source 13A and the first drain 13B may form a first thin film transistor TFT1. The second semiconductor 11B, the gate insulation layer 101, the second gate 12B, the first insulation layer 102, the second source 13C and the second drain 13D may form a second thin film transistor TFT2. The first thin film transistor TFT1 may be electrically connected to the second thin film transistor TFT2, and the first thin film transistor TFT1 and the second thin film transistor TFT2 form the driving circuit C, that is, the driving circuit C may include a plurality of transistors. It should be noted that the structures of the first thin film transistor TFT1 and the second thin film transistor TFT2 in the figure are only examples and may be adjusted to other stacked structures (such as dual gate or bottom gate transistors) or include more transistors according to the actual requirement.

In one embodiment of the present disclosure, as shown in FIG. 1, the electronic device may further include: a third metal layer 14 disposed on the second insulation layer 103, and provided with a first portion 14A, a second portion 14B, a third portion 14C and a fourth portion 14D, wherein the first portion 14A is electrically connected to the first source 13A via a through hole H1, the second portion 14B is electrically connected to the first source 13A via a through hole H2, the third portion 14C is electrically connected to the second drain 13D via a through hole H3, and the fourth portion 14D is electrically connected to the metal portion 13E of the second metal layer 13 a through hole H4, and wherein the photoelectric conversion component 4 is disposed on the third portion 14C of the third metal layer 14 and is electrically connected to the third portion 14C; and a conductive layer 15 disposed on the photoelectric conversion component 4 and electrically connected to the photoelectric conversion component 4. The third portion 14C, the photoelectric conversion component 4 and the conductive layer 15 may be stacked to form a solar cell structure. The photoelectric conversion component 4 may include a light absorbing layer material. The third portion 14C and the conductive layer 15 may serve as the lower electrode and the upper electrode of the solar cell structure, respectively, and signals may be output to the driving circuit C through the upper electrode and the lower electrode.

The first electrode layer 51 is disposed on the second insulation layer 103 and is electrically connected to the fourth portion 14D of the third metal layer 14. The electronic device may further include a third insulation layer 104 disposed on the third metal layer 14, the conductive layer 15 and the first electrode layer 51; a fourth metal layer 16 disposed on the third insulation layer 104 and provided with a fifth portion 16A and a signal transmission line 16B, wherein the fifth portion 16A is electrically connected to the first portion 14A of the third metal layer 14 via a through hole H5, and the signal transmission line 16B is electrically connected to the second portion 14B of the third metal layer 14 and one end of the photoelectric conversion component 4 (or the first electrode layer 51) via through holes H6 and H7, respectively and, more specifically, the signal transmission line 16B is electrically connected to the second portion 14B of the third metal layer 14 via the through hole H6, and the signal transmission line 16B is electrically connected to the conductive layer 15 via the through hole H7; and a passivation layer 105 disposed on the third insulation layer 104 and the fourth metal layer 16. The second electrode layer 52 is disposed on the second substrate 2, and the light modulation layer 3 is disposed between the first electrode layer 51 and the second electrode layer 52. The light modulation layer 3 may be controlled by applying signals to the first electrode layer 51 and the second electrode layer 52, so that the light modulation layer 3 can be switched between a light shielding state and a light transmitting state. In one embodiment of the present disclosure, as shown in FIG. 1, the conductive layer 15 and the first electrode layer 51 may be selectively the same conductive layer, that is, the conductive layer 15 and the first electrode layer 51 are formed using the same photolithography process, so as to simplify the process steps, but it is not limited thereto.

In the present disclosure, the first substrate 1 and the second substrate 2 may respectively be a flexible substrate or a rigid substrate. The materials of the first substrate 1 and the second substrate 2 may include glass, quartz, sapphire, ceramic, plastic, polycarbonate (PC), polyimide (PI), polypropylene (PP), polyethylene terephthalate (PET), polymethylmethacrylate (PMMA), other suitable materials or a combination of the above materials, but the present disclosure is not limited thereto. In the present disclosure, the materials of the first semiconductor 11A and the second semiconductor 11B may each include amorphous silicon, polycrystalline silicon (for example, low temperature polycrystalline silicon (LTPS)), or an oxide semiconductor (for example, indium gallium zinc oxide (IGZO) or indium gallium oxide (IGO)), but the present disclosure is not limited thereto. In addition, the first semiconductor 11A and the second semiconductor 11B may each include doping carriers, such as N-type carriers or P-type carriers. In one embodiment of the present disclosure, the doping carriers of the first semiconductor 11A may be different from the doping carriers of the second semiconductor 11B. For example, the first semiconductor 11A may include N-type carriers to form an N-doped semiconductor; and the second semiconductor 11B may include P-type carriers to form a P-doped semiconductor, but the present disclosure is not limited thereto. In other embodiments (not shown), the first semiconductor 11A may include P-type carriers to form a P-doped semiconductor, and the second semiconductor 11B may include N-type carriers to form an N-doped semiconductor, but the present disclosure is not limited thereto. In the present disclosure, the gate insulation layer 101, the first insulation layer 102, the second insulation layer 103, the third insulation layer 104 and the passivation layer 105 may each include a single-layer or multi-layer insulation layer structure, and the materials of the gate insulation layer 101, the first insulation layer 102, the second insulation layer 103, the third insulation layer 104 and the passivation layer 105 may each include silicon nitride, silicon oxide, silicon oxynitride, silicon carbonitride, aluminum oxide or a combination thereof, but the present disclosure is not limited thereto. In the present disclosure, the first metal layer 12, the second metal layer 13, the third metal layer 14 and the fourth metal layer 16 may each include a metal material, a metal oxide material, an alloy thereof or a combination thereof, for example, may include gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO), but the present disclosure is not limited thereto. In the present disclosure, the materials of the first electrode layer 51 and the second electrode layer 52 may each include a transparent conductive material, such as indium zinc oxide (IZO), indium tin oxide (ITO), indium tin zinc oxide (ITZO), indium gallium zinc oxide (IGZO), aluminum zinc oxide (AZO) or a combination thereof, but the present disclosure is not limited thereto. In the present disclosure, the light modulation layer 3 includes a liquid crystal material or an electrochromic material, and suitable liquid crystal materials may include, for example, polymer dispersed liquid crystal (PDLC), polymer network liquid crystal (PNLC), cholesteric texture liquid crystal, twisted nematic liquid crystal (TN LC), super twisted nematic liquid crystal (STN LC), other suitable liquid crystal materials or a combination thereof, but the present disclosure is not limited thereto. In the present disclosure, the photoelectric conversion component 4 may include an amorphous silicon PIN solar diode, a copper indium gallium selenide solar cell, a perovskite solar cell or a combination thereof, but the present disclosure is not limited thereto.

In one embodiment of the present disclosure, the photoelectric conversion component 4 may absorb the light source L to convert light energy into electrical energy. Therefore, the component or layer between the photoelectric conversion component 4 and the light source L is preferably made of transparent material to improve the light conversion efficiency. In the present disclosure, the material of the conductive layer 15 may include indium zinc oxide (IZO), indium tin oxide (ITO), indium tin zinc oxide (ITZO), indium gallium zinc oxide (IGZO), aluminum zinc oxide (AZO), or a combination thereof, but the present disclosure is not limited thereto.

In the present disclosure, as shown in FIG. 1 and FIG. 2, the photoelectric conversion component 4 may, for example, absorb at least a portion of the light source L and convert it into an electrical signal, and then output the signal to the driving circuit C through the third portion 14C of the third metal layer 14 and the signal transmission line 16B of the fourth metal layer 16. After the driving circuit C converts the DC signal into an AC signal, the AC signal is transmitted to at least one of the first electrode layer 51 and the second electrode layer 52, thereby controlling the light modulation layer 3, but it is not limited thereto. In comparison with using a DC signal to control the light modulation layer 3, using an AC signal to control the light modulation layer 3 may reduce the degradation of the liquid crystal material in the light modulation layer 3 and increase the service life of the electronic device.

In one embodiment of the present disclosure, as shown in FIG. 1, the electronic device may further include: a buffer layer 10 disposed on the first substrate 1, wherein the driving circuit C is disposed on the buffer layer 10. In the present disclosure, the material of the buffer layer 10 may include silicon nitride, silicon oxide, silicon oxynitride, silicon carbonitride or a combination thereof, but the present disclosure is not limited thereto.

In one embodiment of the present disclosure, as shown in FIG. 1, the electronic device may further include: a conductive structure 6 disposed between the first substrate 1 and the second substrate 2, wherein the driving circuit C is disposed between the first substrate 1 and the light modulation layer 3, and the driving circuit C is electrically connected to the second electrode layer 52 via the conductive structure 6. In more detail, the driving circuit C is electrically connected to the conductive structure 6 via the first portion 14A of the third metal layer 14 and/or the fifth portion 16A of the fourth metal layer 16, for example, so as to transmit the signal from the driving circuit C to the second electrode layer 52. In the present disclosure, the conductive structure 6 may include solder bumps, conductive columns (metal columns) or conductive particles or a combination thereof. The conductive structure 6 may include silver, aluminum, nickel, chromium, copper, gold, palladium, platinum, tin, tungsten, rhodium, iridium, ruthenium, magnesium, zinc, alloys thereof, or a combination thereof, but the present disclosure is not limited thereto. In addition, the conductive structure 6 may be formed by using conductive paste (such as silver paste) or anisotropic conductive film (ACF), but the present disclosure is not limited thereto.

In one embodiment of the present disclosure, as shown in FIG. 1, the electronic device may further include: a first spacer S1 disposed between the first substrate 1 and the second substrate 2, wherein the first spacer S1 overlaps with the driving circuit C in a top view direction Z of the first substrate 1. In some embodiments, in the top view direction Z of the first substrate 1, the projection of the first spacer S1 onto the first substrate 1 may be located within the projection of the driving circuit C onto the first substrate 1. In other words, the projection area of the first spacer S1 on the first substrate 1 may be smaller than the projection area of the driving circuit C on the first substrate 1. The first spacer S1 may be used to maintain the thickness of the light modulation layer 3 to reduce damage to components in the electronic device or influence on the dimming uniformity of the light modulation layer 3 in different areas when the electronic device is squeezed by external force. The first spacer S1 may affect the optical performance of the light modulation layer 3 adjacent to the first spacer S1, thereby affecting the transmittance of the electronic device. Therefore, when the first spacer S1 is designed to overlap with the driving circuit C, the light modulation layer 3 in the area overlapping with the driving circuit C is already a non-light-adjustable area. Therefore, the possibility of the first spacer S1 affecting the light-adjustable area (aperture ratio) may be reduced through the above design. In addition, the first spacer S1 may interfere with the photoelectric conversion component 4 receiving the light source L. When the first spacer S1 is designed to overlap with the driving circuit C, the influence of the first spacer S1 on the photoelectric conversion component 4 receiving the light source L may be reduced, thereby improving the effect of the photoelectric conversion component 4. In the present disclosure, the material of the first spacer S1 may include resin, organic material, other suitable materials or a combination thereof, but the present disclosure is not limited thereto. In the present disclosure, the cross-sectional shape of the first spacer S1 is not particularly limited, and may be, for example, a cylinder, a rectangular cylinder, a trapezoidal cylinder, a triangular cylinder, a cone, a triangular pyramid, or other irregular cylinders, but the present disclosure is not limited thereto.

In one embodiment of the present disclosure, as shown in FIG. 1, the electronic device may further include: a second spacer S2 disposed between the first substrate 1 and the second substrate 2. The signal transmission line 16B is electrically connected to one end of the photoelectric conversion component 4. In the top view direction Z of the first substrate 1, the second spacer S2 overlaps the signal transmission line 16B. In addition, the second spacer S2 may affect the optical performance of the light modulation layer 3 adjacent to the second spacer S2. Therefore, when the second spacer S2 is designed to overlap with the signal transmission line 16B, the light modulation layer 3 in the area overlapping with the signal transmission line 16B is already a non-light-adjustable area. Therefore, the possibility of the second spacer S2 affecting the light-adjustable area (aperture ratio) may be reduced through the above design. In addition, the second spacer S2 may interfere with the photoelectric conversion component 4 receiving the light source L. When the second spacer S2 is designed to overlap with the signal transmission line 16B, the influence of the second spacer S2 on the photoelectric conversion component 4 receiving the light source L may be reduced, thereby improving the effect of the photoelectric conversion component 4. In the present disclosure, the second spacer S2 may be made of the same material as or a different material from the first spacer S1, and thus a detailed description is deemed unnecessary.

In one embodiment of the present disclosure, as shown in FIG. 1, in the top view direction Z of the first substrate 1, the photoelectric conversion component 4 is separated from the driving circuit C by a distance; that is, in the top view direction Z of the first substrate 1, the photoelectric conversion component 4 does not overlap with the first thin film transistor TFT1 and the second thin film transistor TFT2 of the driving circuit C. In one embodiment of the present disclosure, as shown in FIG. 1, in the top view direction Z of the first substrate 1, the area in the first semiconductor 11A overlapping with the first gate 12A may be defined as the first channel area A1 of the first thin film transistor TFT1, and the area in the second semiconductor 11B overlapping with the second gate 12B may be defined as the second channel area A2 of the second thin film transistor TFT2, wherein in the top view direction Z of the first substrate 1, the photoelectric conversion component 4 does not overlap with the first channel area A1 of the first thin film transistor TFT1 and the second channel area A2 of the second thin film transistor TFT2; that is, in the top view direction Z of the first substrate 1, the photoelectric conversion component 4 does not overlap with the channel area (for example, the first channel area A1 and the second channel area A2) of the driving circuit C.

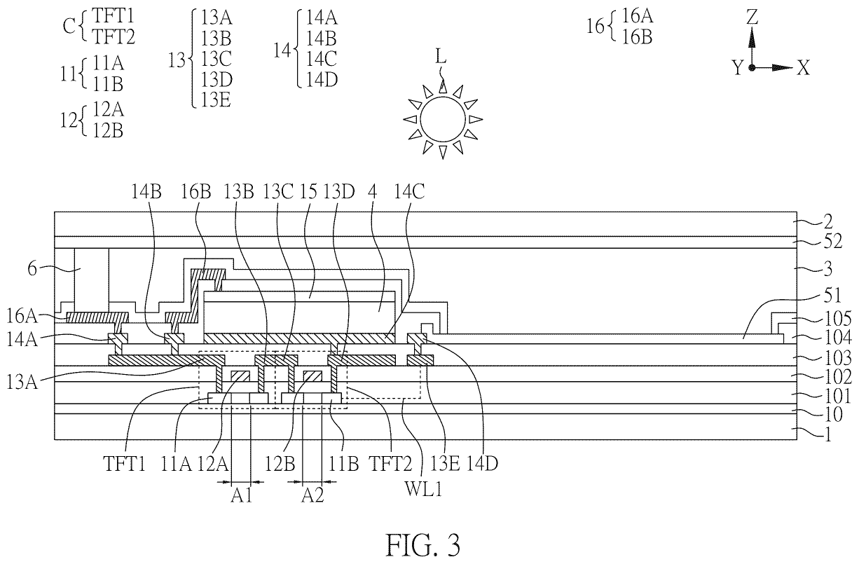

FIG. 3 schematically illustrates a cross-sectional view of an electronic device according to an embodiment of the present disclosure. The electronic device of FIG. 3 is similar to that of FIG. 1, except for the following differences.

In one embodiment of the present disclosure, as shown in FIG. 3, in the top view direction Z of the first substrate 1, the photoelectric conversion component 4 may overlap with the driving circuit C. In more detail, in the top view direction Z of the first substrate 1, the photoelectric conversion component 4 may overlap with the first thin film transistor TFT1 and the second thin film transistor TFT2. In one embodiment of the present disclosure, in the top view direction Z of the first substrate 1, the photoelectric conversion component 4 may overlap with the first channel area A1 of the first thin film transistor TFT1 and the second channel area A2 of the second thin film transistor TFT2. In other words, in the top view direction Z of the first substrate 1, the photoelectric conversion component 4 overlaps with a channel area (for example, the first channel area A1 or the second channel area A2) of the driving circuit C. In this way, the light-adjustable area of the electronic device (that is, the first electrode layer 51 and the second electrode layer 52) may be increased.

In the present disclosure, the features of other components and materials of the electronic device may be as described above and will not be repeated here.

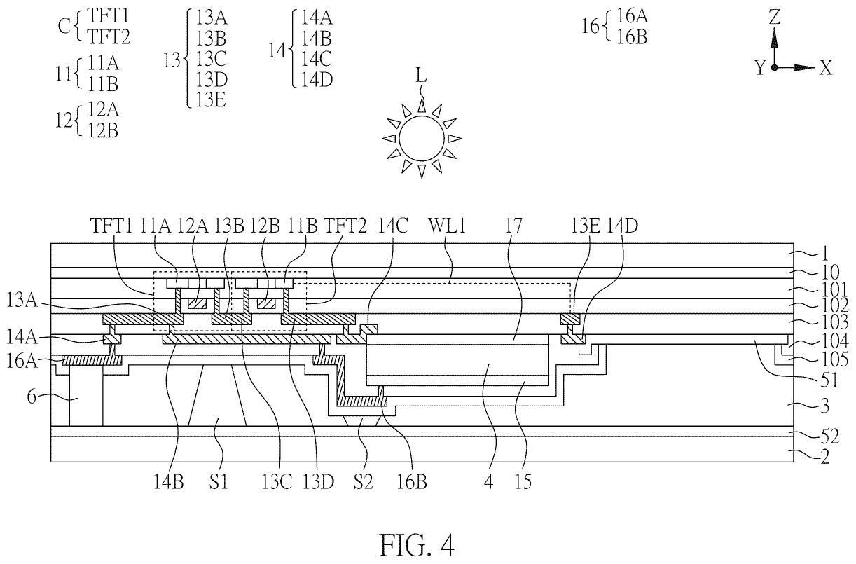

FIG. 4 schematically illustrates a cross-sectional view of an electronic device according to an embodiment of the present disclosure. The electronic device of FIG. 4 is similar to that of FIG. 1, except for the following differences.

In one embodiment of the present disclosure, as shown in FIG. 4, the electronic device further includes a conductive layer 17 electrically connected to the photoelectric conversion component 4, wherein the photoelectric conversion component 4 is disposed between the conductive layer 15 and the conductive layer 17. In this embodiment, the conductive layer 15 and the conductive layer 17 may be used as the upper and lower electrodes of the photoelectric conversion component 4, respectively. The photoelectric conversion component 4 may output signals to the driving circuit C through the upper and lower electrodes. In more detail, the photoelectric conversion component 4 may be electrically connected to the driving circuit C through the conductive layer 17 and the third portion 14C of the third metal layer 14, and the photoelectric conversion component 4 may be electrically connected to the driving circuit C through the conductive layer 15, the signal transmission line 16B of the fourth metal layer 16, and the second portion 14B of the third metal layer 14, thereby respectively outputting signals to the driving circuit C. After using the driving circuit C to convert the DC signal into an AC signal, the AC signal is transmitted to at least one of the first electrode layer 51 and the second electrode layer 52, respectively, thereby controlling the light modulation layer 3, so that the electronic device is able to achieve a light-adjustable effect (such as a light shielding effect or light transmitting effect).

In one embodiment of the present disclosure, as shown in FIG. 4, the conductive layer 17 is closer to the light source L than the conductive layer 15. In this case, the conductive layer 17 is preferably made of a transparent conductive material, while the conductive layer 15 may be selectively made of a transparent conductive material or a non-transparent conductive material (such as a metal material). In one embodiment of the present disclosure, as shown in FIG. 4, the first substrate 1 is disposed closer to the light source L than the second substrate 2, and the driving circuit C is disposed closer to the light source L (for example, but not limited thereto, ambient light) than the light modulation layer 3.

In the present disclosure, since the photoelectric conversion component 4 needs to absorb the light source L to convert light energy into electrical energy, the component between the photoelectric conversion component 4 and the light source L is preferably made of a transparent material or a material with high transparency so as to reduce the impact on the light conversion efficiency. In the present disclosure, the material of the conductive layer 17 may include indium zinc oxide (IZO), indium tin oxide (ITO), indium tin zinc oxide (ITZO), indium gallium zinc oxide (IGZO), aluminum zinc oxide (AZO), or a combination thereof, but the present disclosure is not limited thereto. In one embodiment of the present disclosure, the conductive layer 15 may be made of a transparent or non-transparent material, and suitable materials include metal materials, metal oxide materials, alloys thereof or a combination thereof, such as gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO), but the present disclosure is not limited thereto.

In the present disclosure, the features of other components and materials of the electronic device may be as described above and will not be repeated here.

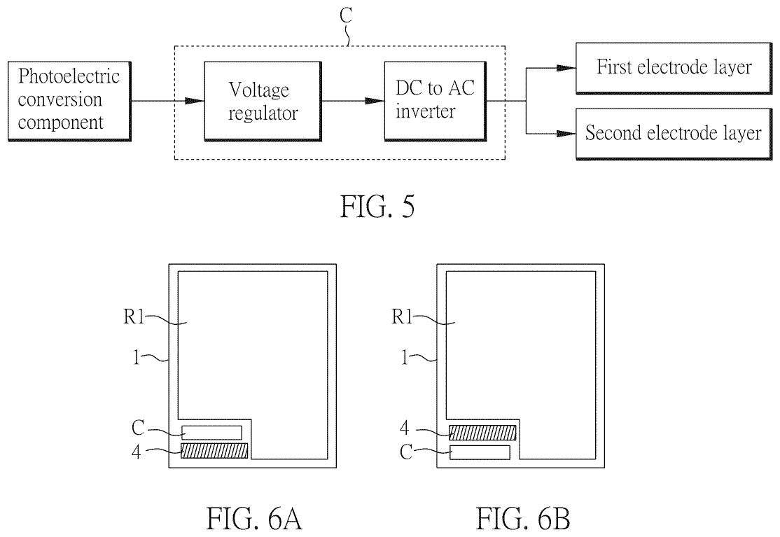

FIG. 5 is a voltage signal block diagram of an electronic device according to an embodiment of the present disclosure.

In one embodiment of the present disclosure, the voltage signal transmission path of the electronic device may be referred to as shown in FIG. 5. After the photoelectric conversion component absorbs at least part of the light source (light energy), the light energy is converted into a voltage signal and input into the driving circuit C. The voltage signal is stabilized and the AC voltage signal is output through the voltage regulator and the DC to AC inverter in the driving circuit C. The output voltage signal is provided to the first electrode layer and/or the second electrode layer, respectively, thereby controlling the light modulation layer 3 (as shown in FIG. 1), so that the electronic device is able to achieve a light shielding or light transmitting effect, but it is not limited thereto. In other embodiments, the driving circuit C may selectively include other circuit components.

FIG. 6A and FIG. 6B schematically illustrate the top views of an electronic device according to an embodiment of the present disclosure.

In one embodiment of the present disclosure, as shown in FIG. 6A and FIG. 6B, the light modulation layer 3 (as shown in FIG. 1) may include at least one light-adjustable area R1, and the light-adjustable area R1 refers to an area in the light modulation layer 3 (as shown in FIG. 1) that can be switched between a light shielding state, a light transmitting state, or a haze state. In more detail, with reference to FIG. 1, FIG. 6A and FIG. 6B, the light-adjustable area R1 in the light modulation layer 3 may be controlled to switch between a light shielding state (or a haze state) and a light transmitting state by applying signals to the first electrode layer 51 and the second electrode layer 52. In one embodiment of the present disclosure, with reference to FIG. 1, FIG. 6A and FIG. 6B, the light-adjustable area R1 refers to, for example, the overlapping area of the first conductive layer 51 and the second conductive layer 52 in the light modulation layer 3, but it is not limited thereto. In one embodiment of the present disclosure, as shown in FIG. 6A and FIG. 6B, in the top view direction Z of the first substrate 1, the light-adjustable area R1 may not overlap with the driving circuit C and/or the photoelectric component 4, but the present disclosure is not limited thereto.

In one embodiment of the present disclosure, as shown in FIG. 6A, in the top view direction Z of the first substrate 1, the driving circuit C may not overlap with the photoelectric conversion component 4, wherein the driving circuit C may be disposed between the light-adjustable area R1 and the photoelectric conversion component 4, but it is not limited thereto. In one embodiment of the present disclosure, as shown in FIG. 6B, in the top view direction Z of the first substrate 1, the driving circuit C may not overlap with the photoelectric conversion component 4, and the photoelectric conversion component 4 may be disposed between the light-adjustable area R1 and the driving circuit C, but the present disclosure is not limited thereto. In one embodiment of the present disclosure, although not shown in the figures, in the top view direction Z of the first substrate 1, the driving circuit C may at least partially overlap with the photoelectric conversion component 4, but the present disclosure is not limited thereto. It should be noted that, in the top view direction Z of the first substrate 1, the size, shape, and position relationship (overlapping relationship) of the driving circuit C, the photoelectric component 4, and the light-adjustable area R1 may be adjusted as required.

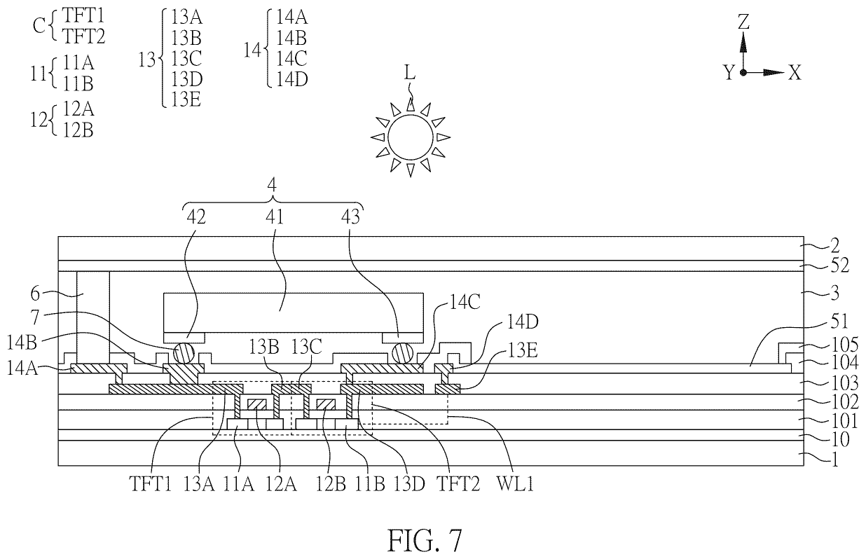

FIG. 7 schematically illustrates a cross-sectional view of an electronic device according to an embodiment of the present disclosure. The electronic device of FIG. 7 is similar to that of FIG. 1, except for the following differences.

In one embodiment of the present disclosure, as shown in FIG. 7, the photoelectric conversion component 4 may include a main body 41 (including light absorbing material), a first conductive pad 42 and a second conductive pad 43. The first conductive pad 42 and the second conductive pad 43 may be respectively electrically connected to the main body 41. The first conductive pad 42 and the second conductive pad 43 may be disposed at, for example, the same side of the main body 41, such as a side away from the light source L, but it is not limited thereto. The photoelectric conversion component 4 may be electrically connected to the driving circuit C through a conductive material 7 to transmit the signal to the driving circuit C. In more detail, as shown in FIG. 7, the photoelectric conversion component 4 may be electrically connected to the driving circuit C through the conductive material 7, the second portion 14B and the third portion 14C of the third metal layer 14, respectively, so that signals provided by the photoelectric conversion component 4 may be transmitted from the first conductive pad 42 and the second conductive pad 43 to the driving circuit C, and then the driving circuit C is used to convert the DC signal into an AC signal for being transmitted to the first electrode layer 51 or the second electrode layer 52.

In the present disclosure, the conductive material 7 may include solder bumps, metal columns or conductive particles. The conductive material 7 may include silver, aluminum, nickel, chromium, copper, gold, palladium, platinum, tin, tungsten, rhodium, iridium, ruthenium, magnesium, zinc, alloys thereof or a combination thereof, but the present disclosure is not limited thereto. In addition, the conductive material 7 may be formed by using conductive paste (such as silver paste) or anisotropic conductive film (ACF), but the present disclosure is not limited thereto. In one embodiment of the present disclosure, the conductive material 7 may include silver paste. In the present disclosure, the features of other components and materials of the electronic device may be as described above and will not be described in detail herein. In the top view direction Z of the first substrate 1, the thickness of the conductive material 7 may be smaller than the thickness of the conductive structure 6. In one embodiment of the present disclosure, in the top view direction Z of the first substrate 1, the thickness of the conductive structure 6 may be greater than the thickness of the photoelectric conversion component 4. In one embodiment of the present disclosure, in a cross section, the width of the conductive material 7 may be smaller than the width of the second portion 14B, or the width of the conductive material 7 may be smaller than the width of the third portion 14C. In one embodiment of the present disclosure, in a cross section, the width of the first conductive pad 42 may be greater than or equal to the width of the conductive material 7, and/or the width of the second conductive pad 43 may be greater than or equal to the width of the conductive material 7. In one embodiment of the present disclosure, in a cross section, projection of the first semiconductor 11A and the second semiconductor 11B onto the first substrate 1 may be located within a projection of the main body 41 onto the first substrate 1. In other words, the projection area of the first semiconductor 11A and the second semiconductor 11B on the first substrate 1 may be smaller than the projection area of the main body 41 on the first substrate 1.

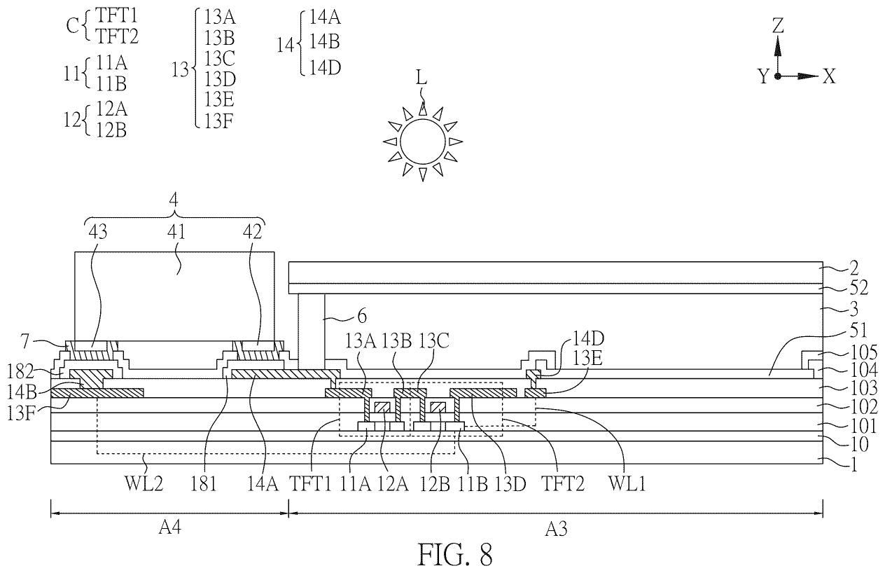

FIG. 8 schematically illustrates a cross-sectional view of an electronic device according to an embodiment of the present disclosure. The electronic device of FIG. 8 is similar to that of FIG. 1, except for the following differences.

In one embodiment of the present disclosure, as shown in FIG. 8, the electronic device may include: a first substrate 1; a second substrate 2 disposed opposite to the first substrate 1, wherein the first substrate 1 has a first area A3 overlapping with the second substrate 2, and a second area A4 not overlapping with the second substrate 2; a light modulation layer 3 disposed between the first substrate 1 and the second substrate 2; a first electrode layer 51 disposed between the first substrate 1 and the light modulation layer 3; a second electrode layer 52 disposed between the second substrate 2 and the light modulation layer 3; a photoelectric conversion component 4 disposed on the second area A4 of the first substrate 1; and a driving circuit C disposed between the first substrate 1 and the second substrate 2, wherein the driving circuit C is electrically connected to the photoelectric conversion component 4, and the driving circuit C is electrically connected to the first electrode layer 51 and the second electrode layer 52, respectively. In one embodiment of the present disclosure, as shown in FIG. 8, in the top view direction Z of the first substrate 1, the photoelectric conversion component 4 and the second substrate 2 do not overlap. In one embodiment of the present disclosure, in the top view direction Z of the first substrate 1, the photoelectric conversion component 4 and the driving circuit C do not overlap. In one embodiment of the present disclosure, in the top view direction Z of the first substrate 1, the photoelectric conversion component 4 does not overlap with the first electrode layer 51 and the second electrode layer 52.

In one embodiment of the present disclosure, as shown in FIG. 8, the photoelectric conversion component 4 may include a main body 41, a first conductive pad 42, and a second conductive pad 43. The first conductive pad 42 and the second conductive pad 43 are each electrically connected to the main body 41. The photoelectric conversion component 4 may be electrically connected to the driving circuit C through a conductive material 7 to transmit signals to the driving circuit C. In more detail, as shown in FIG. 8, the first conductive pad 42 of the photoelectric conversion component 4 may be electrically connected to the driving circuit C through the conductive material 7, the conductive layer 181 (for example, it may be in the same layer as the first electrode layer 51, but not limited thereto) and the first portion 14A of the third metal layer 14, and the second conductive pad 43 of the photoelectric conversion component 4 may be electrically connected to the driving circuit C through the conductive material 7, the conductive layer 182 (for example, it may be in the same layer as the first electrode layer 51, but not limited thereto), the second portion 14B of the third metal layer 14 and the metal portion 13F of the second metal layer 13 (the dotted line in the figure indicates that the metal portion 13F is electrically connected to the driving circuit C through the line WL2), thereby transmitting the signals provided by the photoelectric conversion component 4 to the driving circuit C. The driving circuit C is electrically connected to the first electrode layer 51 via the metal portion 13E of the second metal layer 13 and the fourth portion 14D of the third metal layer 14 (the dotted line in the figure indicates that the metal portion 13E is electrically connected to the driving circuit C through the line WL1), and the driving circuit C is electrically connected to the second electrode layer 52 via the first portion 14A of the third metal layer 14 and the conductive structure 6, so as to provide signals (voltage) to the first electrode layer 51 and the second electrode layer 52, respectively, thereby controlling the light modulation layer 3, so that the electronic device is able to achieve a light shielding or light transmitting effect.

In the present disclosure, the conductive layer 181 and the conductive layer 182 may be the same layer as the first electrode layer 51, which may simplify the process steps, but it is not limited thereto. Therefore, the material of the conductive layer 181 and the conductive layer 182 may be the same as that of the first electrode layer 51, and thus a detailed description is deemed unnecessary. In other embodiments (not shown), the conductive layer 181 and the conductive layer 182 may be different layers from the first electrode layer 51. In the present disclosure, the conductive material 7 may include solder bumps, metal columns or conductive particles, and the conductive material 7 may include silver, aluminum, nickel, chromium, copper, gold, palladium, platinum, tin, tungsten, rhodium, iridium, ruthenium, magnesium, zinc, alloys thereof or a combination thereof, but the present disclosure is not limited thereto. In addition, the conductive material 7 may be formed by using conductive paste (such as silver paste) or anisotropic conductive film (ACF), but the present disclosure is not limited thereto. In one embodiment of the present disclosure, the conductive material 7 may be an anisotropic conductive film. In the present disclosure, the features of other components and materials of the electronic device may be as described above and will not be described in detail herein. It should be noted that, although there is no seal shown in the embodiments of FIG. 1, FIGS. 3-4 and FIGS. 7-8, a seal may be disposed between the first substrate 1 and the second substrate 2 to surround the light modulation layer 3. A portion of the seal may be disposed, for example, between the light modulation layer 3 and the conductive structure 6, or the conductive structure 6 may be disposed, for example, between the light modulation layer 3 and the seal.

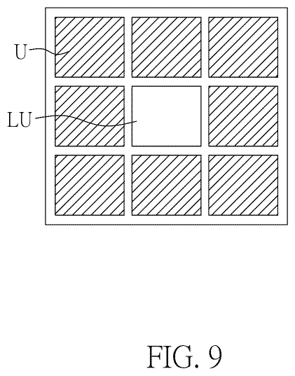

FIG. 9 schematically illustrates the top view of an electronic device according to an embodiment of the present disclosure.

In one embodiment of the present disclosure, as shown in FIG. 9, the electronic device may be applied to a smart window (such as a liquid crystal window), and the smart window may include a plurality of sub-units U arranged adjacent to each other (such as an array arrangement), wherein the cross-sectional stacking structure of the sub-units U may refer to any one of the aforementioned FIGS. 1, 3, 4, 7 and 8, and thus a detailed description is deemed unnecessary.

In one embodiment of the present disclosure, as shown in FIG. 9, the smart window (for example, a liquid crystal window) may selectively include or not include another sub-unit LU, and the sub-unit LU may be adjacent to a plurality of sub-units U. For example, a plurality of sub-units U may be arranged around the sub-unit LU, but the present disclosure is not limited thereto. The sub-unit LU may include liquid crystal material, for example, but the sub-unit LU may not include a driving circuit C and a photoelectric conversion component 4 (as shown in FIG. 1) or other components (such as a first electrode layer 51 or a second electrode layer 52). Therefore, the liquid crystal material in the sub-unit LU cannot, for example, control the switching of light, such as the switching between a light shielding state (or a haze state) and a light transmitting state, but it is not limited thereto.

In the present disclosure, by designing the arrangement of a sub-unit U and another sub-unit LU, a smart window (for example, a liquid crystal window) may provide a pattern or text display. For example, as shown in FIG. 9, when exposed to sunlight, a plurality of sub-units U may be switched to a light shielding state, while another sub-unit LU may be a light transmitting state, so that the smart window (for example, a liquid crystal window) displays the English letter “O” or the like, but the present disclosure is not limited thereto. The arrangement, quantity, size and appearance of the sub-unit U and another sub-unit LU may be adjusted according to requirements.

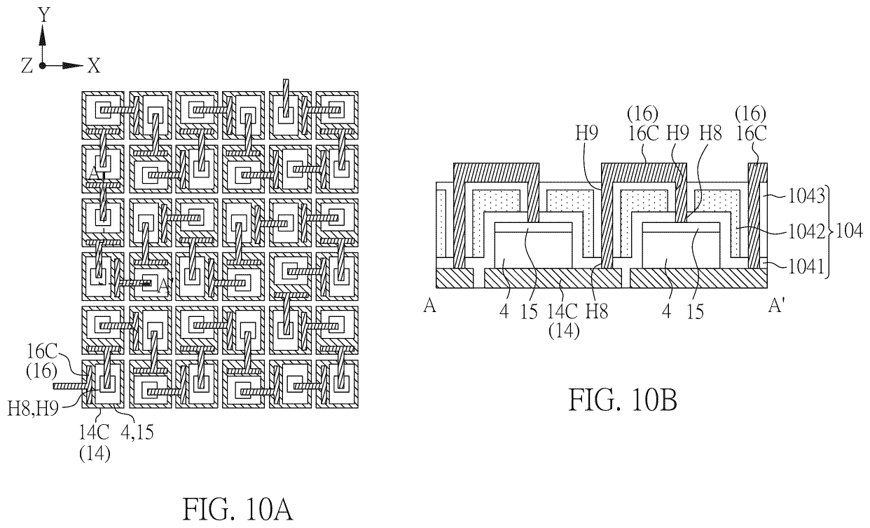

FIG. 10A schematically illustrates the top view of a photoelectric conversion component according to an embodiment of the present disclosure, and FIG. 10B is a cross-sectional view of the photoelectric conversion component taken along line A-A′ of FIG. 10A. For the convenience of explanation, some components are omitted in the figure.

In one embodiment of the present disclosure, as shown in FIG. 10A, the electronic device may include a plurality of photoelectric conversion components 4 disposed adjacent to each other, and the plurality of photoelectric conversion components 4 are connected in series, but it is not limited thereto. In more detail, as shown in FIG. 10A and FIG. 10B, the photoelectric conversion component 4 may be electrically connected to one end of the sixth portion 16C of the fourth metal layer 16 through the conductive layer 15, and the other end of the sixth portion 16C of the fourth metal layer 16 may be electrically connected to the third portion 14C of the third metal layer 14 of another photoelectric conversion component 4, so that multiple photoelectric conversion components 4 are connected in series with each other, thereby allowing signals to be transmitted to the driving circuit C (as shown in FIG. 1).

In one embodiment of the present disclosure, as shown in FIG. 10B, the third insulation layer 104 may include a multi-layer structure. For example, the third insulation layer 104 may include a first sub-insulation layer 1041, a second sub-insulation layer 1042 and a third sub-insulation layer 1043, and the second sub-insulation layer 1042 is disposed between the first sub-insulation layer 1041 and the third sub-insulation layer 1043, wherein the sixth portion 16C of the fourth metal layer 16 may be electrically connected to the third portion 14C of the third metal layer 14 and the conductive layer 15, respectively, via the through hole H8 of the first sub-insulation layer 1041 and the through hole H9 of the third sub-insulation layer 1043, but it is not limited thereto, while the number of sub-insulation layers of the third insulation layer 104 may be adjusted according to the needs.

When the thickness of the light modulation layer 3 (as shown in FIG. 1) increases, the required driving voltage increases. Therefore, by setting a plurality of photoelectric conversion components 4 and connecting the plurality of photoelectric conversion components 4 in series to provide a series-connected voltage to control the light modulation layer 3 (as shown in FIG. 1), so that the light modulation layer 3 (as shown in FIG. 1) may be switched between a light shielding state and a light transmitting state.

The present disclosure combines the photoelectric conversion component 4 with the driving circuit C. The photoelectric conversion component 4 converts light energy into electrical energy for being provided to the driving circuit C. The driving circuit C may, for example, convert a DC signal into an AC signal, and then provide the converted signal to the first electrode layer 51 and the second electrode layer 52, so that the electronic device may control the light modulation layer 3 without the need for an additional external power supply, thereby achieving a power saving effect.

The aforementioned specific embodiments should be construed as merely illustrative, and not limiting the rest of the present disclosure in any way.

1. An electronic device, comprising:
a first substrate;
a second substrate disposed opposite to the first substrate;
a light modulation layer disposed between the first substrate and the second substrate;
a first electrode layer disposed between the first substrate and the light modulation layer;
a second electrode layer disposed between the second substrate and the light modulation layer;
a photoelectric conversion component disposed between the first substrate and the second substrate; and
a driving circuit disposed between the first substrate and the second substrate, wherein the driving circuit is electrically connected to the photoelectric conversion component, and the driving circuit is electrically connected to the first electrode layer and the second electrode layer, respectively.

2. The electronic device as claimed in claim 1, further comprising: a conductive structure disposed between the first substrate and the second substrate, wherein the driving circuit is disposed between the first substrate and the light modulation layer, and the driving circuit is electrically connected to the second electrode layer through the conductive structure.

3. The electronic device as claimed in claim 1, further comprising a first spacer disposed between the first substrate and the second substrate, wherein the first spacer overlaps with the driving circuit in a top view direction of the first substrate.

4. The electronic device as described in claim 1, further comprising:
a second spacer disposed between the first substrate and the second substrate; and
a signal transmission line electrically connected to one end of the photoelectric conversion component,
wherein the second spacer overlaps with the signal transmission line in a top view direction of the first substrate.

5. The electronic device as claimed in claim 1, wherein the photoelectric conversion component overlaps with a channel area of the driving circuit in a top view direction of the first substrate.

6. The electronic device as claimed in claim 1, wherein the photoelectric conversion component and the driving circuit are separated by a distance in a top view direction of the first substrate.

7. The electronic device as claimed in claim 1, wherein the driving circuit includes a plurality of transistors.

8. The electronic device as claimed in claim 1, wherein the light modulation layer includes a liquid crystal material or an electrochromic material.

9. The electronic device as claimed in claim 1, wherein the photoelectric conversion component includes an amorphous silicon PIN solar diode, a copper indium gallium selenide solar cell, a perovskite solar cell or a combination thereof.

10. The electronic device as claimed in claim 1, further comprising:
a semiconductor layer including a first semiconductor and a second semiconductor;
a first metal layer including a first gate and a second gate, wherein the first gate is disposed opposite to the first semiconductor layer, and the second gate is disposed opposite to the second semiconductor layer; and
a second metal layer including a first source, a first drain, a second source, and a second drain, wherein the first source and the first drain are each electrically connected to the first semiconductor layer, the second source and the second drain are each electrically connected to the second semiconductor layer, and the first drain is electrically connected to the second source.

11. The electronic device as claimed in claim 10, wherein the second metal layer further includes a metal portion electrically connected to the driving circuit.

12. The electronic device as claimed in claim 11, further comprising a third metal layer including a first portion, a second portion, a third portion and a fourth portion, wherein the first portion is electrically connected to the first source, the second portion is electrically connected to the first source, the third portion is electrically connected to the second drain, the fourth portion is electrically connected to the metal portion of the second metal layer, and the photoelectric conversion component is disposed on the third portion and electrically connected to the third portion.

13. The electronic device as claimed in claim 12, further comprising a conductive layer disposed on the photoelectric conversion component and electrically connected to the photoelectric conversion component.

14. The electronic device as claimed in claim 12, wherein the first electrode layer is electrically connected to the fourth portion of the third metal layer.

15. The electronic device as claimed in claim 13, further comprising a fourth metal layer including a fifth portion and a signal transmission line, wherein the fifth portion is electrically connected to the first portion, the signal transmission line is electrically connected to the second portion, and the signal transmission line is electrically connected to the conductive layer.

16. The electronic device as claimed in claim 1, further comprising: a first conductive layer disposed on the photoelectric conversion component and electrically connected to the photoelectric conversion component; and a second conductive layer electrically connected to the photoelectric conversion component, wherein the photoelectric conversion component is disposed between the first conductive layer and the second conductive layer.

17. The electronic device as claimed in claim 16, wherein the second conductive layer is made of a transparent conductive material.

18. The electronic device as claimed in claim 1, further comprising a buffer layer disposed on the first substrate, wherein the driving circuit is disposed on the buffer layer.

19. The electronic device as claimed in claim 1, wherein the driving circuit converts a DC signal from the photoelectric conversion component into an AC signal, and transmits the AC signal to the first electrode layer and the second electrode layer.

20. An electronic device, comprising:
a first substrate;
a second substrate disposed opposite to the first substrate, wherein the first substrate has a first area overlapping with the second substrate, and a second area not overlapping with the second substrate;
a light modulation layer disposed between the first substrate and the second substrate;
a first electrode layer disposed between the first substrate and the light modulation layer;
a second electrode layer disposed between the second substrate and the light modulation layer;
a photoelectric conversion component disposed on the second area of the first substrate; and
a driving circuit disposed between the first substrate and the second substrate, wherein the driving circuit is electrically connected to the photoelectric conversion component, and the driving circuit is electrically connected to the first electrode layer and the second electrode layer, respectively.
